(19) United States
(12) Patent Application Publication
(10) Pub. No.: US 2025/0279331 A1
(43) Pub. Date: Sep. 4, 2025

(54) HEAT DISSIPATION STRUCTURE FOR HEATING ELEMENT AND HOUSING STRUCTURE FOR BRAKE SYSTEM HAVING THE SAME

(71) Applicant: HL MANDO CORPORATION, Gyeonggi-do (KR)

(72) Inventors: Hanjun LEE, Gyeonggi-do (KR); Kawnseek KIM, Gyeonggi-do (KR); Heechul JUNG, Gyeonggi-do (KR); Hyunchul LEE, Gyeonggi-do (KR)

(21) Appl. No.: 18/986,693

(22) Filed: Dec. 18, 2024

(30) Foreign Application Priority Data
Mar. 4, 2024 (KR) 10-2024-0030725

(51) Int. Cl. H01L 23/373; H01L 23/00; H01L 23/367; H01L 23/498; H01L 25/07; H05K 1/02

(52) U.S. Cl. CPC H01L 23/3735; H01L 23/3675; H01L 23/498; H01L 24/32; H05K 1/0203; H01L 25/072; H01L 2224/32157

(57) ABSTRACT

A heat dissipation structure is provided. The heat dissipation structure according to an aspect of the present disclosure includes a PCB substrate having a first heat dissipation pad having a predetermined area on one surface; a heating element coupled onto the heat dissipation pad by a coupling part, the heating element having one surface disposed adjacent to the heat dissipation pad and the other surface opposite to the one surface; a heat sink having one surface disposed of contact on the heating element; and a heat transfer material comprising a first region portion interposed between the other surface of the heating element and one surface of the heat sink.

### CROSS-REFERENCE TO RELATED APPLICATION

This application claims priority to and the benefit of Korean Patent Application No. 10-2024-0030725, filed on Mar. 4, 2024, the disclosure of which is incorporated herein by reference in its entirety.

### BACKGROUND

### 1. Technical Field

The present disclosure relates to a heat dissipation structure for a heating element and a housing structure for a brake system having the same. More specifically, the present disclosure relates to a heat dissipation structure capable of increasing the heat dissipation efficiency of a heating element and a housing structure for a brake system to which such a heat dissipation structure is applied.

### 2. Discussion of Related Art

The brake system uses a three-phase motor as an actuator for pressurization. To drive this, AC signals must be output through each of the three terminals, and corresponding signals are output through an inverter circuit.

In this case, the inverter circuit consists of six switching elements, and since it is vulnerable to heat generation due to high-speed switching and high current, heat dissipation measures are essential.

Conventionally, the heating element was applied with thermal grease and mounted on a PCB. In addition, by forming a plurality of vias on the PCB equipped with the heating element, heat generated from the heating element was radiated to the heat sink structure provided on the opposite side of the PCB of the heating element.

However, this method had a problem of poor heat dissipation efficiency because vias were formed through the PCB and heat dissipation was performed through the substrate.

### SUMMARY

The present disclosure is to solve the above problems, and the present disclosure is directed to providing a heat dissipation structure capable of increasing the heat dissipation efficiency of a heating element, and a housing structure for a brake system to which such a structure is applied.

The present disclosure is also directed to providing a heat dissipation structure configured to dissipate heat directly from a heating element to a heat sink structure, and a housing structure for a brake system to which such a structure is applied.

The present disclosure is also directed to providing a heat dissipation structure capable of dissipating heat from a heating element without passing through a PCB substrate on which the heating element is mounted, and a housing structure for a brake system to which such a structure is applied.

The problems of the present disclosure are not limited to those mentioned above, and other problems not mentioned will be clearly understood by those of ordinary skill in the art from the following description.

The objects of the present disclosure are not limited to the above-described objects, and other objects that are not mentioned will be able to be clearly understood by those skilled in the art to which the present disclosure pertains from the following description.

According to an aspect of the present disclosure, provided is a heat dissipation structure, including: a PCB substrate having a first heat dissipation pad having a predetermined area on one surface; a heating element coupled onto the first heat dissipation pad, the heating element having one surface contacting the first heat dissipation pad and the other surface opposite to the one surface; a heat sink having one surface disposed of contact on the heating element; and a heat transfer material comprising a first region portion interposed between the other surface of the heating element and one surface of the heat sink.

In this case, the area of the first heat dissipation pad may correspond to the area of the one surface of the heating element.

In this case, the area of one surface of the heat sink may correspond to the area of the other surface of the heating element.

In this case, the heat transfer material may include thermal grease.

In this case, the heat sink may form a part of a housing surrounding the PCB substrate and the heating element to protect the PCB substrate and the heating element of the heat dissipation structure.

In this case, the area of the first heat dissipation pad may be formed to be wider than the area of one surface of the heating element.

In this case, the first heat dissipation pad may be a first electrode pad, and one surface of the heating element in contact with the first electrode pad may be a part of a first electrode of the heating element in contact with the first electrode pad.

In this case, the area of one surface of the heat sink may correspond to the area of the first heat dissipation pad, and the heat transfer material may include a second region portion between a portion of the first heat dissipation pad that does not come into contact with the heating element on a side of the first region portion and a portion of the heat sink facing the portion of the first heat dissipation pad.

In this case, the first heat dissipation pad may be formed to have a wider width on both sides in the width direction of the heating element, and the heat transfer material may have the second region portion formed on both sides in the width direction of the first region portion.

In this case, one surface of the heat sink may be formed as a plane, and the thickness of the heat transfer material of the second region portion may be thicker than the thickness of the heat transfer material of the first region portion.

In this case, the first heat dissipation pad may be formed to have a wider width on one side in the width direction of the heating element, and the heat transfer material may have the second region portion formed on one side in the width direction of the first region portion.

In this case, one surface of the heat sink may include a first bottom surface adjacent to the first region portion and a second bottom surface protruding toward the heat dissipation pad more than the first bottom surface, and the thickness of the heat transfer material of the first region portion may be formed to be the same as the thickness of the heat transfer material of the second region portion.

In this case, the heating element may have a second electrode, a second heat dissipation pad having a predetermined area and in contact with the second electrode may be provided on the PCB, and the area of the second heat dissipation pad may be wider than that of the second electrode.

In this case, the heating element may be a switching element for an inverter circuit, the first electrode may be a drain electrode, and the second electrode may be a source electrode.

According to another aspect of the present disclosure, provided is a housing structure for a brake system, including: a housing with built-in PCB substrate for a brake system; a heat dissipation pad having a predetermined area and disposed on the PCB substrate; a heating element coupled onto the heat dissipation pad, the heating element having one surface disposed adjacent to the heat dissipation pad and the other surface opposite to the one surface; a heat sink having one surface disposed of contact on the heating element; and a heat transfer material comprising a first region portion interposed between the other surface of the heating element and one surface of the heat sink.

In this case, the area of the heat dissipation pad may be formed to correspond to or be larger than the area of the one surface of the heating element.

In this case, the area of one surface of the heat sink may correspond to the area of the other surface of the heating element.

In this case, the heat sink may form a part of the housing.

In this case, the area of one surface of the heat sink may correspond to the area of the heat dissipation pad, and the heat transfer material may include a second region portion between a portion of the heat dissipation pad that does not come into contact with the heating element on a side of the first region portion and a portion of the heat sink facing the portion of the heat dissipation pad.

In this case, the heat transfer material may have the second region portion formed on one side or both sides in the width direction of the first region portion.

In this case, one surface of the heat sink may be formed as a plane, and the thickness of the heat transfer material of the second region portion may be thicker than the thickness of the heat transfer material of the first region portion.

In this case, one surface of the heat sink may include a first bottom surface adjacent to the first region portion and a second bottom surface protruding toward the heat dissipation pad more than the first bottom surface, and the thickness of the heat transfer material of the first region portion may be formed to be the same as the thickness of the heat transfer material of the second region portion.

In this case, a plurality of the heat dissipation pads may be provided on the PCB substrate, a plurality of heating elements spaced apart from each other may be provided on the plurality of heat dissipation pads, respectively, a plurality of heat sinks may be provided on the plurality of heating elements, respectively, and the plurality of heat sinks may be integrally connected to the housing.

In this case, the heating element may be a switching element for an inverter circuit.

### BRIEF DESCRIPTION OF THE DRAWINGS

The above and other objects, features and advantages of the present disclosure will become more apparent to those of ordinary skill in the art by describing exemplary embodiments thereof in detail with reference to the accompanying drawings, in which:

FIG. 1 is a perspective view of a heat dissipation structure according to a first embodiment of the present disclosure;

FIG. 2 is a plan view illustrating a region in which a heat dissipation pad contacting a heating element is formed on a PCB substrate of a heat dissipation structure according to a first embodiment of the present disclosure;

FIG. 3 is a cross-sectional view of FIG. 1 in a heat dissipation structure according to a first embodiment of the present disclosure;

FIG. 4 is a perspective view of a heat dissipation structure according to a second embodiment of the present disclosure;

FIG. 5 is a plan view illustrating a region in which a heat dissipation pad contacting a heating element is formed on a PCB substrate of a heat dissipation structure according to a second embodiment of the present disclosure;

FIG. 6 is a cross-sectional view of FIG. 4 in a heat dissipation structure according to a second embodiment of the present disclosure;

FIG. 7 is a perspective view of a heat dissipation structure according to a third embodiment of the present disclosure;

FIG. 8 is a plan view illustrating a region in which a heat dissipation pad contacting a heating element is formed on a PCB substrate of a heat dissipation structure according to a third embodiment of the present disclosure;

FIG. 9 is a cross-sectional view of FIG. 3 in a heat dissipation structure according to a third embodiment of the present disclosure;

FIG. 10 is a perspective view of a housing structure for a brake system to which a heat dissipation structure according to an exemplary embodiment of the present disclosure is applied;

### DETAILED DESCRIPTION OF EXEMPLARY EMBODIMENTS

Hereinafter, embodiments of the present disclosure will be described in detail so that those skilled in the art to which the present disclosure pertains can easily carry out the embodiments. The present disclosure may be implemented in many different forms and is not limited to the embodiments described herein. In order to clearly describe the present disclosure, portions not related to the description are omitted from the accompanying drawings, and the same or similar components are denoted by the same reference numerals throughout the specification.

The words and terms used in the specification and the claims are not limitedly construed as their ordinary or dictionary meanings, and should be construed as meaning and concept consistent with the technical spirit of the present disclosure in accordance with the principle that the inventors can define terms and concepts in order to best describe their invention.

In the specification, it should be understood that the terms such as “comprise” or “have” are intended to specify the presence of features, numbers, steps, operations, components, parts, or combinations thereof described in the specification and do not preclude the possibility of the presence or addition of one or more other features, numbers, steps, operations, components, parts, or combinations thereof.

In the drawings of this specification, the thickness and size of components are exaggerated for clarity of explanation.

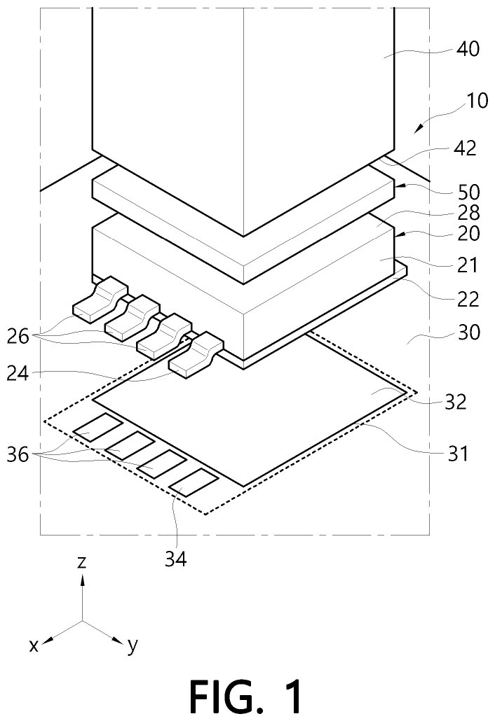

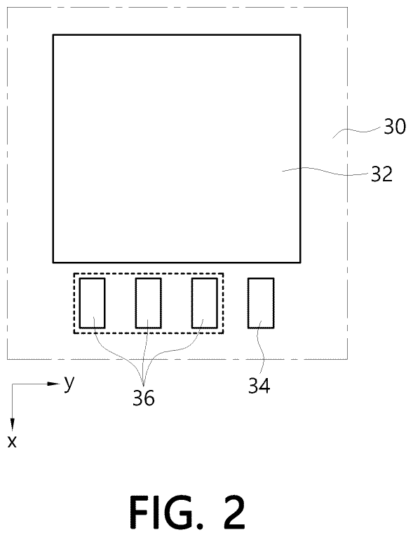

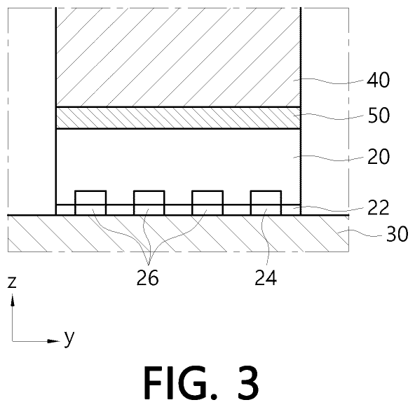

FIG. 1 is a perspective view of a heat dissipation structure according to a first embodiment of the present disclosure. FIG. 2 is a plan view illustrating a region in which a heat dissipation pad contacting a heating element is formed on a PCB substrate of a heat dissipation structure according to a first embodiment of the present disclosure. FIG. 3 is a cross-sectional view of FIG. 1 in a heat dissipation structure according to a first embodiment of the present disclosure.

Referring to FIGS. 1 to 3, the heat dissipation structure 10 according to an exemplary embodiment of the present disclosure may include a PCB substrate 30, a heating element 20, and a heat sink 40.

In the first embodiment of the present disclosure, a heat dissipation pad 31 and a heating element 20 are installed on the PCB substrate 30. In this case, a plurality of elements for driving a brake system, for example, a field effect transistor (FET), a shunt, etc., may be combined on the PCB substrate 30.

In the first embodiment of the present disclosure, a heat dissipation pad 31 is provided on the PCB substrate 30. In this case, according to the first embodiment of the present disclosure, the heat dissipation pad 31 may be, as an electrode pad formed on a PCB substrate to be electrically connected to an electrode of the FET, a drain electrode pad 32 electrically connected to a drain electrode among the FET electrodes. That is, in the first embodiment of the present disclosure, the drain electrode pad 32 may be used as a heat dissipation pad 31 for dissipating heat from the heating element 20.

In the first embodiment of the present disclosure, the FET, which is the heating element 20, includes one gate electrode 24, three source electrodes 26, and a drain electrode 22. In addition, a gate electrode pad 34, a source electrode pad 36, and a drain electrode pad 32 respectively connected to the gate electrode 24, the source electrode 26, and the drain electrode 22 are formed on the PCB substrate 30.

In an embodiment of the present disclosure, the heat dissipation pad 31 may be formed to have an area equal to or wider than the FET so that heat dissipation can be made from the heating element 20 placed on the heat dissipation pad 31, for example, from the FET provided inside the housing of the brake system.

In the first embodiment of the present disclosure, the heat dissipation pad 31, that is, the drain electrode pad 32, may be formed to have an area corresponding to the contact region of the drain electrode 22 of the FET.

In the first embodiment of the present disclosure, the heating element 20 contacts and is coupled onto the heat dissipation pad 31.

In an embodiment of the present disclosure, the heating element 20 may be, for example, an electric field effect transistor (FET) as a switching element of an inverter circuit for driving an actuator for pressurization in a brake system.

In this case, the FET may include a gate, a drain, and a source electrode (or an electrode terminal).

In FIG. 2, the upper part of the heat dissipation pad 31, i.e., the drain electrode pad 32, is a region in contact with the drain electrode of the FET, reference numeral 36 is, as a source electrode pad, a region in contact with the source electrode, and reference numeral 34 is, as a gate electrode pad, a region in contact with the gate electrode.

In the present embodiment, the number of FETs applied to the brake system may consist of six. Since the structure of the FET and the description of the gate electrode, drain electrode, and source electrode are well known, a detailed description thereof will be omitted.

Meanwhile, in an embodiment of the present disclosure, a structure in which one heating element 20 is connected to the PCB substrate 30 and the heat sink 40 will be mainly described.

In an embodiment of the present disclosure, the heating element 20, for example, FET may include a hexahedral body 21 as shown in FIG. 1. However, the shape of the body 21 of the heating element 20 is not limited thereto. The heating element 20 may be formed such that the source electrode and the gate electrode protrude from the body 21 in a positive direction of the x-axis when viewed in FIG. 1. As can be seen in FIG. 1, the source and gate electrodes may be provided in a form bent toward the substrate.

In the body 21 of the heating element 20, a drain electrode 22 may be formed on the lower surface of the body 21 facing the substrate 30 when viewed in FIG. 1. The drain electrode 22 may be coupled onto the substrate by a coupling member not shown, such as a bolt.

Meanwhile, according to the first embodiment of the present disclosure, a heat transfer material 50, for example, a thermal grease, may be applied to an upper portion of the heating element 20 coupled onto the heat dissipation pad 31 on the substrate 30, and the heat sink 40 may be positioned on the heat transfer material 50.

In the first embodiment of the present disclosure, the shape of the bottom surface 42 of the heat sink 40 facing the top surface 28 of the heating element 20 may correspond to the shape of the top surface 28 of the heating element 20. The heat transfer material 50 may be applied to facilitate heat transfer between the bottom surface 42 of the heat sink 40 and the top surface 28 of the heating element 20. In this case, the heat transfer material 50 may be thermal grease, but is not limited thereto.

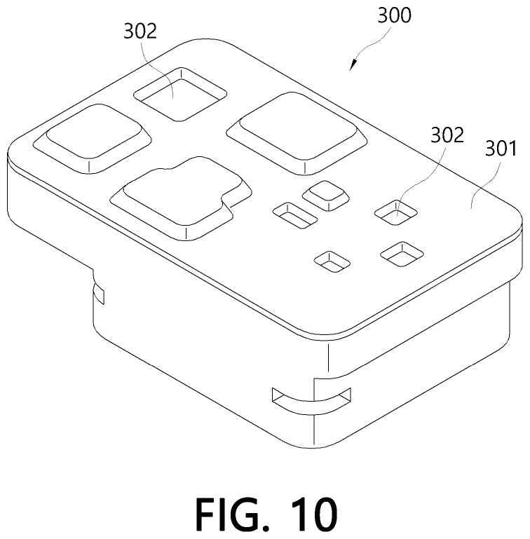

In an embodiment of the present disclosure, the heat sink 40 may form a part of a housing (301 in FIG. 10) surrounding the PCB substrate 30 and the heating element 20 to protect the PCB substrate 30 and the heating element 20.

The heat sink 40 may be formed of a metal or non-metal material having high thermal conductivity such as aluminum. Accordingly, heat generated from the heating element 20 may be transferred to the housing (301 in FIG. 10) through the heat sink 40, and then be discharged to the outside of the housing (301 in FIG. 10).

In an embodiment of the present disclosure, a plurality of FETs may be provided inside the housing (301 in FIG. 10), and in each of the plurality of FETs, the heat sink 40 may be in contact with one surface of the FET to transfer heat through thermal grease.

Since the plurality of heat sinks 40 connected to the plurality of FETs may be integrally formed in the housing (301 in FIG. 10), heat generated while the plurality of FETs operate may be radiated to the outside of the housing (301 in FIG. 10) through the plurality of heat sinks 40.

According to an embodiment of the present disclosure, heat generated by the heating element 20 is not radiated to the heat sink 40 through the substrate 30, and is radiated directly to the housing (301 in FIG. 10) through the thermal grease and the heat sink, which are heat transfer materials, thereby increasing heat dissipation efficiency and simplifying the heat dissipation structure.

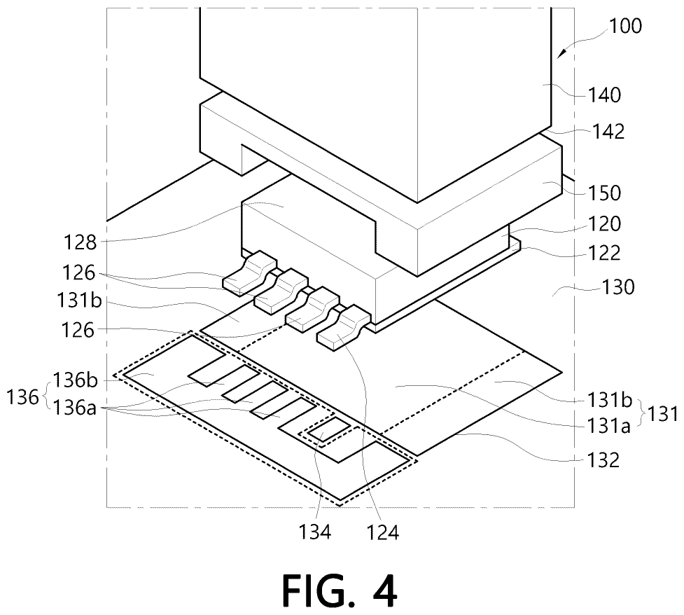

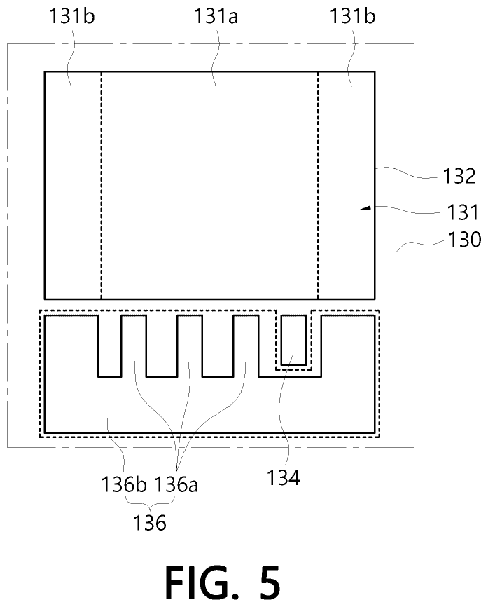

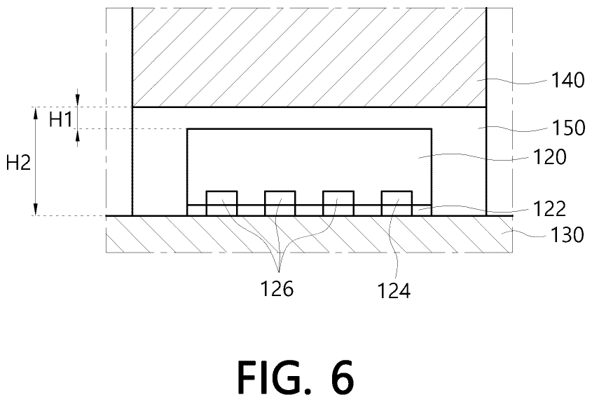

FIG. 4 is a perspective view of a heat dissipation structure according to a second embodiment of the present disclosure. FIG. 5 is a plan view illustrating a region in which a heat dissipation pad contacting a heating element is formed on a PCB substrate of a heat dissipation structure according to a second embodiment of the present disclosure. FIG. 6 is a cross-sectional view of FIG. 4 in a heat dissipation structure according to a second embodiment of the present disclosure.

Similar to the first embodiment, the heat dissipation structure 100 according to the second embodiment of the present disclosure may include a PCB substrate 130, a heating element 120, and a heat sink 140. Hereinafter, in describing the heat dissipation structure 100 according to the second embodiment, a configuration distinguished from the first embodiment will be mainly described.

The heat dissipation structure 100 according to the second embodiment of the present disclosure is formed to have a heat dissipation pad 131, for example, a drain electrode 132 of the FET, wider than an area of one surface of the heating element 120, that is, a surface where the heating element 120 contacts the heat dissipation pad 131 on the substrate, compared to the first embodiment.

In the second embodiment of the present disclosure, the FET, which is the heating element 120, includes one gate electrode 124, three source electrodes 126, and a drain electrode 122. In addition, a gate electrode pad 134, a source electrode pad 136, and a drain electrode pad 132 respectively connected to the gate electrode 124, the source electrode 126, and the drain electrode 122 are formed on the PCB substrate 130.

In this case, in FIG. 5, a first region portion 131a of the upper portion of the heat dissipation pad 131 is a contact region with the drain electrode 122 of the FET, reference numeral 136 is a source electrode pad region with contact with the source electrode 126, and reference numeral 134 is a gate electrode pad region with contact with the gate electrode 124.

In this case, the top surface of the heat dissipation pad 131 may be divided into a first region portion 131a that is a region in contact with the heating element 120 and a second region portion 131b that is not in contact with the heating element 120. According to the second embodiment of the present disclosure, the heat dissipation pad 131 is formed in a quadrangular shape, the first region portion 131a is located in the center, and the second region portion 131b is located on both sides in the width direction of the heating element 120 around the first region portion 131a.

According to the second embodiment of the present disclosure, the area of the bottom surface 142 of the heat sink 140 may correspond to the area of the heat dissipation pad 131. Accordingly, as shown in FIGS. 4 and 6, the area of the bottom surface 142 of the heat sink 140 may be formed to be wider than the area of the top surface 128 of the heating element 120.

According to the second embodiment of the present disclosure, a heat transfer material 150, that is, thermal grease, is applied to the first region portion 131a and the second region portion 131b.

Accordingly, as can be seen in FIG. 6, the thickness H2 of the heat transfer material 150 in the second region portion 131b may be formed to be thicker than the thickness H1 of the heat transfer material 150 in the first region portion 131a.

According to the second embodiment of the present disclosure, heat generated by the heating element 120 is transferred to the heat sink 140 side through the top surface 124 of the heating element 120 in the case of the first region portion 131a.

In addition, some heat generated by the heating element 120 is transferred to the heat sink 140 through the heat transfer material 150 on the top of the second region portion 131b, that is, thermal grease, through the heat dissipation pad 131.

In addition, in the second embodiment of the present disclosure, the source electrode pad 136 includes a third region 136a with which the source electrode 126 is in contact and a fourth region 136b with which the source electrode 126 is not in contact. In this case, the third region 136a and the fourth region 136b are formed to be electrically energized. In addition, the fourth region 136b may be formed wider than the third region 136a. Accordingly, heat generated through the source electrode 126 may be transferred from the third region 136a to the fourth region 136b, and radiated to the air from the fourth region 136b.

Therefore, in the first embodiment, the amount of heat transfer in the second embodiment may be increased compared to the case where the heat generated by the heating element 20 is transferred to the heat sink 40 side only through the top surface of the heating element 20.

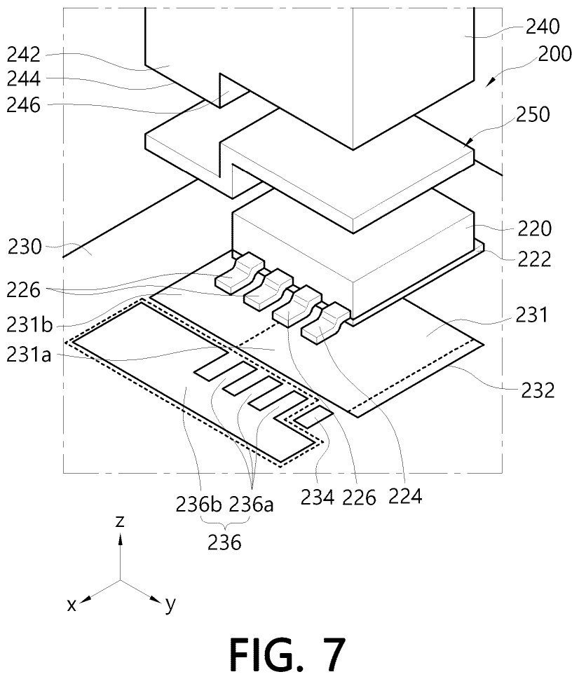

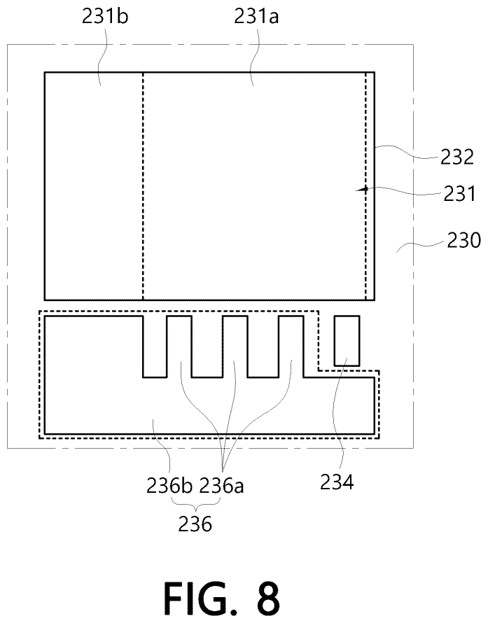

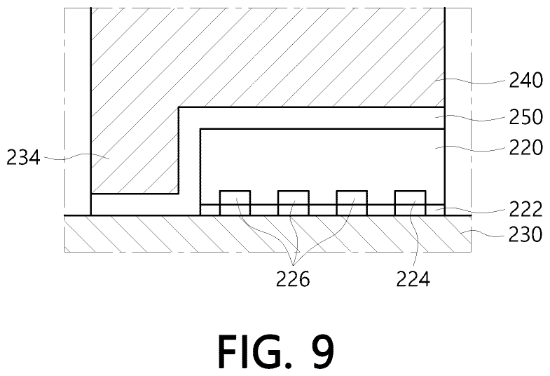

FIG. 7 is a perspective view of a heat dissipation structure according to a third embodiment of the present disclosure. FIG. 8 is a plan view illustrating a region in which a heat dissipation pad contacting a heating element is formed on a PCB substrate of a heat dissipation structure according to a third embodiment of the present disclosure. FIG. 9 is a cross-sectional view of FIG. 3 in a heat dissipation structure according to a third embodiment of the present disclosure.

Compared to the second embodiment, the heat dissipation structure 200 according to the third embodiment of the present disclosure is the same as the second embodiment in a structure where the area of the heat dissipation pad 231 is wider than the area of the heating element 220, but the position of the heating element 220 is different from that of the heat dissipation structure according to the second embodiment.

In the third embodiment of the present disclosure, the FET, which is the heating element 220, includes one gate electrode 224, three source electrodes 226, and a drain electrode 222. In addition, a gate electrode pad 234, a source electrode pad 236, and a drain electrode pad 232 respectively connected to the gate electrode 224, the source electrode 226, and the drain electrode 222 are formed on the PCB substrate 230.

In this case, in FIG. 8, a first region portion 231a of the upper portion of the heat dissipation pad is a contact region with the drain electrode 222 of the FET, reference numeral 236 is a source electrode pad region with contact with the source electrode 226, and reference numeral 234 is a gate electrode pad region with contact with the gate electrode 124.

In the third embodiment of the present disclosure, the heating element 220 is formed to be biased to one side in the width direction of the heat dissipation pad 231, for example, to the right when viewed in FIG. 7.

Accordingly, in FIG. 8, a first region portion 231a is located on the right side of the heat dissipation pad 231, and a second region portion 231b is disposed to the left of the first region portion 231a. Accordingly, as shown in FIGS. 7 and 9, the second region portion 231b is disposed to the left of the heating element 220.

Meanwhile, according to the third embodiment of the present disclosure, in the heat sink 240, the end surface 244 of the heat sink 240 located above the second region portion 231b of the heat dissipation pad 231 protrudes toward the heat dissipation pad 231, that is, downward when viewed in FIG. 9, to form a protrusion 242.

In this case, the height at which the heat sink 240 protrudes toward the heat dissipation pad 231 may be formed to correspond to the height of the heating element 220.

As described above, the second region portion 231b of the bottom surface of the heat sink 240 that does not face the heating element 220 is formed to protrude toward the heat dissipation pad 231, thereby narrowing the distance between the protrusion 242 of the heat sink 240 and the heat dissipation pad 231. Accordingly, the application amount of the heat transfer material 250, that is, thermal grease, disposed between the protrusion 242 of the heat sink 240 and the heat dissipation pad 231 may be reduced.

As in the second embodiment, if the thickness in the second region portion 131b is thicker than the thickness in the first region portion 131a between the heat sink 140 and the heating element 120, the distance between the heat sink 140 and the heat dissipation pad 131 becomes far, and depending on the viscosity of the heat transfer material, that is, the thermal grease, a case in which a heat transfer material, that is, thermal grease, is not filled in the space of the second region portion between the heat sink 140 and the heat dissipation pad 131 may occur.

As such, it may be necessary to form the distance between the heat sink 140 and the heat dissipation pad 131 as short as possible to prevent thermal grease from not being filled in the space between the heat sink 140 and the heat dissipation pad 131.

In the third embodiment of the present disclosure, in order to maintain a short distance between the heat sink 240 and the heat dissipation pad 231, the protrusion 242 is formed in the heat sink 240 portion disposed in the second region portion 231b to protrude toward the heat dissipation pad 31.

Accordingly, the heat transfer material applied to the first region portion 231a and the second region portion 231b, that is, the thickness of the thermal grease, may be formed to have almost the same thickness.

In this case, the side surface 246 of the protrusion 242 is formed to be spaced apart from the side surface of the heating element 220 by a predetermined distance. In this case, the distance between the side surface of the protrusion 242 and the side surface of the heating element 220 may be formed to be the same as or similar to the thickness of the heat transfer material, that is, the thermal grease, applied to the first region portion.

In the third embodiment of the present disclosure, the thickness of the thermal grease applied to the first region portion 231a and the thickness of the thermal grease applied to the second region portion 231b may be formed differently or the same, depending on the design.

In this case, if the thickness of the heat transfer material, that is, thermal grease, is formed equally over the entire region, mass productivity increases and the possibility of contact failure between the heat dissipation pad 231 and the heat sink 240 decreases.

And, in the third embodiment, since the distance that heat travels through the heat transfer material, that is, thermal grease, is shortened, heat passing through thermal grease can be prevented from being transferred to the heating element 220.

If the distance of heat transfer through thermal grease in the second region portion 131b is longer than in the first region portion 131a as in the second embodiment, while heat is transferred from the second region portion 131b, some heat may be transferred to the heating element 120 on the side of the second region portion 131b, so there is a possibility that heat transfer efficiency may decrease.

Meanwhile, according to the third embodiment of the present disclosure, the heat sink 240 may form a part of the housing (301 in FIG. 10), similar to the first and second embodiments.

In this case, the protrusion 242 formed on the bottom surface of the heat sink 240 may be manufactured in consideration of the size and shape of the heating element 220 when designing the housing (301 in FIG. 10).

Meanwhile, in the third embodiment of the present disclosure, similar to the second embodiment, the source electrode pad 236 includes a third region 236a with which the source electrode 226 is in contact and a fourth region 236b with which the source electrode 226 is not in contact. In this case, the third region 236a and the fourth region 236b are formed to be electrically energized. In addition, the fourth region 236b may be formed wider than the third region 236a. Accordingly, heat generated through the source electrode 226 may be transferred from the third region 236a to the fourth region 236b, and radiated to the air from the fourth region 236b.

Meanwhile, in the present embodiment, a configuration in which the protrusion 242 protrudes from one side of the bottom surface of the heat sink 240 has been illustrated, but, as another example, if two second region portions are formed on both sides of the heat dissipation pad as in the second embodiment, a plurality of protrusions 242 may be formed corresponding to the number of second region portions.

In addition, the third embodiment illustrated that the cross-section of the protrusion 242 has a quadrangular shape corresponding to the quadrangular-shaped second region of the heat dissipation pad, but, it may be possible for the cross-section of the protrusion 242 to have a rectangular or square shape or various shapes, for example, an “L” shape or a “L” shape cross-section, depending on the shape of the second region portion of the heat dissipation pad 231.

FIG. 10 is an external perspective view of a housing structure 300 for a brake system to which the heat dissipation structure according to the first to third embodiments of the present disclosure is applied.

Referring to FIG. 10, the heat dissipation structures 10, 100, and 200 according to various embodiments of the present disclosure described with reference to FIGS. 1 to 9 may be included in the housing structure 300 for a brake system. The structures of the heat dissipation structures 10, 100, and 200 according to various embodiments of the present disclosure have been described in detail in the above-described embodiments, and thus a description thereof will be omitted.

In an embodiment of the present disclosure, a plurality of FETs as a plurality of heating elements may be provided inside the housing structure 300 for a brake system.

In this case, as described in the first to third embodiments described above, a heat sink in contact with a plurality of FETs is provided to dissipate heat of the plurality of FETs, and the heat sink may be formed as a part of the housing in FIG. 10.

In this case, the heat sinks 40, 140, and 240 described in the first to third embodiments may be disposed in a portion formed as a groove 302 on the surface of the housing 301 in FIG. 10.

In this case, the thickness of the heat sink 40, 140, and 240 may have a predetermined thickness to dissipate heat generated from the heating element, and the housing may be designed in consideration of the location and thickness of the heat sink.

As in the exemplary housing structure 300 for a brake system of the present disclosure, when the overall design of the housing 301 is made in consideration of the thickness of the heat sink 40, 140, and 240, if the thickness of the heat sink at a position where the FET is disposed does not need to be thick, the housing 301 may be configured such that the heat sink is disposed at a position where the groove 302 is formed when viewed from the outside. The size and thickness of the groove 302 may be designed in consideration of the position and the degree of heat generation of the heat sink.

In addition, the location and shape of the heat sink formed in the housing 301 may be designed differently depending on the location, size, and degree of heat generation of the heating element with which the heat sink is in contact.

As described above, the heat dissipation structure according to various embodiments of the present disclosure can be applied as a heat dissipation structure of a heating element, especially a FET element mounted on a circuit board provided for a brake system, and can efficiently increase heat dissipation efficiency while having a simple structure and mass productivity.

Although the FET mounted on the circuit board for the brake system has been exemplified above as a heating element, as long as the structure is configured to directly contact the heat sink through a heat transfer material, that is, thermal grease, the heat dissipation structure exemplarily described in various embodiments of the present disclosure can be applied. According to the configuration, the heat dissipation structure according to an exemplary embodiment of the present disclosure can increase heat dissipation efficiency since heat is dissipated by the heat sink directly contacting the heating element.

In addition, heat is not transferred to the heat sink side through the PCB, so heat dissipation efficiency can be increased.

The heat dissipation structure according to an exemplary embodiment of the present disclosure can increase heat dissipation efficiency by configuring an area of the heat dissipation pad of the PCB substrate to be wider than an area in contact with the heating element and allowing heat to be dissipated from the heat dissipation pad to the heat sink.

In addition, the heat dissipation structure according to an exemplary embodiment of the present disclosure can increase heat dissipation efficiency by configuring the heat sink as part of the housing for a brake system, allowing the housing to act as a heat sink.

It should be understood that the effects of the present disclosure are not limited to the above-described effects, and include all effects inferable from a configuration of the invention described in detailed descriptions or claims of the present disclosure. Although embodiments of the present disclosure have been described, the spirit of the present disclosure is not limited by the embodiments presented in the specification. Those skilled in the art who understand the spirit of the present disclosure will be able to easily suggest other embodiments by adding, changing, deleting, or adding components within the scope of the same spirit, but this will also be included within the scope of the spirit of the present disclosure.

What is claimed is:

1. A heat dissipation structure, comprising:
a PCB substrate having a first heat dissipation pad having a predetermined area on one surface;
a heating element coupled onto the first heat dissipation pad, the heating element having one surface contacting the first heat dissipation pad and the other surface opposite to the one surface;
a heat sink having one surface disposed of contact on the heating element; and
a heat transfer material comprising a first region portion interposed between the other surface of the heating element and one surface of the heat sink.

2. The heat dissipation structure of claim 1, wherein the area of the first heat dissipation pad corresponds to the area of the one surface of the heating element.

3. The heat dissipation structure of claim 1, wherein the area of one surface of the heat sink corresponds to the area of the other surface of the heating element.

4. The heat dissipation structure of claim 1, wherein the heat transfer material comprises thermal grease.

5. The heat dissipation structure of claim 1, wherein the heat sink forms a part of a housing surrounding the PCB substrate and the heating element to protect the PCB substrate and the heating element of the heat dissipation structure.

6. The heat dissipation structure of claim 1, wherein the area of the first heat dissipation pad is wider than the area of one surface of the heating element.

7. The heat dissipation structure of claim 6,
wherein the first heat dissipation pad is a first electrode pad, and
one surface of the heating element in contact with the first electrode pad is a part of a first electrode of the heating element in contact with the first electrode pad.

8. The heat dissipation structure of claim 7,
wherein the area of one surface of the heat sink corresponds to the area of the first heat dissipation pad, and
the heat transfer material comprises a second region portion between a portion of the first heat dissipation pad that does not come into contact with the heating element on a side of the first region portion and a portion of the heat sink facing the portion of the first heat dissipation pad.

9. The heat dissipation structure of claim 8,
wherein the first heat dissipation pad is formed to have a wider width on both sides in the width direction of the heating element, and
the heat transfer material has the second region portion formed on both sides in the width direction of the first region portion.

10. The heat dissipation structure of claim 9,
wherein one surface of the heat sink is formed as a plane, and
the thickness of the heat transfer material of the second region portion is thicker than the thickness of the heat transfer material of the first region portion.

11. The heat dissipation structure of claim 8,
wherein the first heat dissipation pad is formed to have a wider width on one side in the width direction of the heating element, and
the heat transfer material has the second region portion formed on one side in the width direction of the first region portion.

12. The heat dissipation structure of claim 11,
wherein one surface of the heat sink comprises a first bottom surface adjacent to the first region portion and a second bottom surface protruding toward the heat dissipation pad more than the first bottom surface, and
the thickness of the heat transfer material of the first region portion is formed to be the same as the thickness of the heat transfer material of the second region portion.

13. The heat dissipation structure of claim 7,
wherein the heating element has a second electrode,
a second heat dissipation pad having a predetermined area and in contact with the second electrode is provided on the PCB, and
the area of the second heat dissipation pad is wider than that of the second electrode.

14. The heat dissipation structure of claim 13,
wherein the heating element is a switching element for an inverter circuit,
the first electrode is a drain electrode, and
the second electrode is a source electrode.

15. A housing structure for a brake system, comprising:
a housing with built-in PCB substrate for a brake system;
a heat dissipation pad having a predetermined area and disposed on the PCB substrate;
a heating element coupled onto the heat dissipation pad, the heating element having one surface disposed adjacent to the heat dissipation pad and the other surface opposite to the one surface;
a heat sink having one surface disposed of contact on the heating element; and
a heat transfer material comprising a first region portion interposed between the other surface of the heating element and one surface of the heat sink.

16. The housing structure for a brake system of claim 15, wherein the area of the heat dissipation pad is formed to correspond to or be larger than the area of the one surface of the heating element.

17. The housing structure for a brake system of claim 15, wherein the area of one surface of the heat sink corresponds to the area of the other surface of the heating element.

18. The housing structure for a brake system of claim 15, wherein the heat sink forms a part of the housing.

19. The housing structure for a brake system of claim 15,
wherein the area of one surface of the heat sink corresponds to the area of the heat dissipation pad, and
the heat transfer material comprises a second region portion between a portion of the heat dissipation pad that does not come into contact with the heating element on a side of the first region portion and a portion of the heat sink facing the portion of the heat dissipation pad.

20. The housing structure for a brake system of claim 15,
wherein a plurality of the heat dissipation pads are provided on the PCB substrate,
a plurality of heating elements spaced apart from each other are provided on the plurality of heat dissipation pads, respectively,
a plurality of heat sinks are provided on the plurality of heating elements, respectively, and
the plurality of heat sinks are integrally connected to the housing.
